(19) United States
(12) Patent Application Publication
(10) Pub. No.: US 2010/0065871 A1
(43) Pub. Date: Mar. 18, 2010

(54) POLYMERS WITH TRANSMISSION INTO THE ULTRAVIOLET

(76) Inventors: Richard A. Pethrick, Glasgow (GB); Martin David Dawson, Glasgow (GB); Erdan Gu, Glasgow (GB); Allan R. Mackintosh, Glasgow (GB); Alexander Jan-Christoph Kuehne, Glasgow (GB)

Correspondence Address: MYERS BIGEL SIBLEY & SAJOVEC, PO BOX 37428, RALEIGH, NC, 27627, US

(21) Appl. No.: 12/516,631

(22) PCT Filed: Nov. 29, 2007
(86) PCT No.: PCT/GB07/04579

§ 371 Date: Oct. 1, 2009

(30) Foreign Application Priority Data
Nov. 29, 2006 (GB) 0623936.2

(51) Int. Cl. H01L 33/00; C08G 77/04; C08F 230/08; C09K 11/06; B05D 5/06; C08J 3/28; C07F 7/02

(52) U.S. Cl. 257/98; 528/10; 526/279; 522/99; 522/148; 522/64; 522/49; 522/66; 252/301.35; 427/515; 556/445; 257/E33.06

(57) ABSTRACT

An ultra violet light transmitting polymer is obtainable by the polymerisation of at least one compound having a substantially non UV absorbing core group comprising; linear or branched aliphatic hydrocarbons which may contain an aliphatic ring; or polydialkylsiloxanes. The compounds have at least one functional group comprising formula (A), (B) or (C):and each of the groups —R³— are, independently, linking groups which may be present or absent and, where present, may be a C₁ to C₁₀ hydrocarbon chain, which may contain an ether linkage. Methods for producing the polymers and uses for the polymers are also described.

### FIELD OF THE INVENTION

The present invention relates to the provision of novel polymers, which can transmit light from the deep ultraviolet region of the spectrum, including methods for their manufacture and use.

### BACKGROUND TO THE INVENTION

Gallium nitride semiconductor light emitting diode (LED) technology is now the basis of a multi billion dollar worldwide industry covering such markets as full colour outdoor displays and solid state lighting. Individual LED devices are typically encapsulated in lensed polymer domes, which serve to protect the LED structure but also foster directionality of output and more efficient light extraction. Some 400 million of these encapsulated LEDs are currently produced worldwide each month.

However, where use of light in the UV/violet spectral region is desired, existing source technology, including LEDs, has poorly covered the UV/Violet spectral region. Traditionally, low-functionality mainframe ion lasers or filtered lamp sources have had to serve. The recent emergence of gallium nitride laser diode technology has not addressed this need, because of limited spectral coverage, poor spatial mode characteristics and limited functionality. The spatial coherence properties of laser sources provide further limitations in imaging applications.

Very recently, however, this emitter technology has begun to be extended into the deep ultraviolet (250-350 nm wavelength) which is largely uncovered by existing solid-state sources and is recognized to open up many new applications in areas such as detection of biohazardous agents, water-, air- and food-sterilization, high-density data storage, covert communications and improved solid-state lighting.

The 250 nm-350 nm region presents a number of difficulties in terms of encapsulation of laser diode devices. Within this region there are very few inorganic and organic materials that are transparent. Inorganic materials such as quartz, sapphire and diamond are prohibitively expensive in terms of raw material and processing, and offer poor flexibility. The initial 250 to 350 nm commercial LEDs which have emerged in the past year are therefore mounted in TO (Titanium Optical) cans and provided with windows of quartz for example. They are therefore bulky, expensive and labour intensive in manufacture and do not promote efficient light extraction or volume scaling. In addition where the use of micro LED arrays is contemplated, the existing materials are not suitable for providing the desired arrays of microlenses for the micro array.

Polymeric materials are utilised in the encapsulation of visible light emitting LEDs, as described above, but most polymeric materials are intrinsically opaque in the UV region. Existing polymers have very low transmission of light with a wavelength below 350 nm.

It is an object of the invention to provide polymers for use in the transmission of UV light that avoid or at least minimise one or more of the aforementioned disadvantages.

### DESCRIPTION OF THE INVENTION

Accordingly the present invention provides an ultra violet light transmitting polymer obtainable by the polymerisation of at least one compound of general formula I:

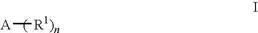

wherein n is a positive integer and A is a substantially non UV absorbing core group comprising;

linear or branched aliphatic hydrocarbons which may contain an aliphatic ring; or

polydialkylsiloxanes of general formula II:

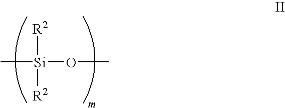

wherein each of the groups R² are independently a C₁-C₁₀ alkyl or cycloalkyl group and m is a positive integer and the polydialkylsiloxane chain may be branched; or

the compound of general formula I is a polydialkylsiloxane of general formula III:

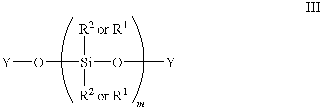

wherein the groups Y are, independently, end capping groups of the form:

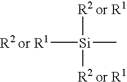

and

R² and m have the same meaning as before and the polydialkylsiloxane chain may be branched; and

wherein each R¹ is independently, a functional group comprising:

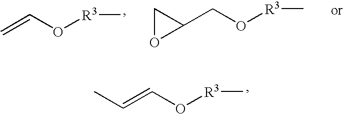

and each of the groups —R³— are, independently, linking groups which may be present or absent and, where present, may be a C₁ to C₁₀ hydrocarbon chain, which may contain an ether linkage.

It will be understood by those skilled in the art that the structures shown above in relation to compounds of general formula II and III above are generalised in that the polydialkyl siloxanes compounds from which they are derived may be branched.

Preferably the polydialkylsiloxanes of general formula II have a molecular mass of from 740 to 64000.

Preferably polydialkylsiloxanes of general formula III have a molecular mass of from 700 to 45000. Preferably in polydialklsiloxanes of general formula III the ratio of R¹ to R² groups is between 1:8 and 1:16. These proportions of functional groups R¹ can provide polymers of the invention with an advantageous high degree of cross linking.

The polymers of the invention transmit UV light in the ultraviolet, generally of from 245 nm to 350 nm wavelength, but they may transmit at even lower wavelengths, down to 220 nm or lower in come cases. It will be understood that the polymers of the invention may also transmit light of higher (visible) wavelengths and can be used in applications that require this. The polymers of the invention can be used to encapsulate LEDs and can also be formed into microlenses, graded index lenses or microfluidics networks. Where micro pixellated gallium nitride LEDs as described, for example in PCT/GB2004/000360, and are formed to produce UV light, then the polymers of the invention can be used to form microlens arrays for encapsulation, collimation and projection of the output of these devices.

By utilising one or more compounds of general formula I polymers of the invention have good transparency to deep UV light (245-350 nm). The core groups A have no substantial UV absorbing components and the functional groups R¹, also have low UV absorbance, especially when fully polymerised.

The functional groups employed, vinyl ethers and glycidyl ethers have ether oxygens which do absorb some UV light, however these ether oxygens have been found to be essential to providing the desired reactivity when making a polymer of this invention by the methods described hereafter.

Optionally the polymers of the invention may contain other substances (dopants), for example to improve the refractive index. Dopants can include materials such as bisphenol A, nano particulate silica, POSS (polyhedral oligiomeric silisesquioxane)and nanoclays such as closite™, for example. However, such additives are added in only limited amounts to avoid reducing the UV transparency.

POSS and nano particulate silica dopants are preferably prepared using silane monomers, or a mixture of silane monomers, comprising at least a portion of organic groups that are functionalised, for example with an epoxy or amine function. This produces functionalised POSS and nano silica particles.

If desired functionalised nano silica particles can be prepared with a core of silica and an outer shell containing the functional groups. The core can be formed from condensation of appropriate silane monomers such as tetraethylorthosilicate, for example, in a sol gel process (for example as described in J.Phys; Conference Series; 26 (2006) 371-374; S Tabatabaei et al). The outer shell can be added by then reacting silane monomers, which include appropriate functionalised organic groups, onto the core. The principle is illustrated in Scheme 1 below wherein the organic groups R can be, for example, an alkyl group such as butyl or they may functionalised with a reactive function, such as an epoxy or an amine function. Both functionalised and non-functionalised groups R may be employed to give the desired properties.

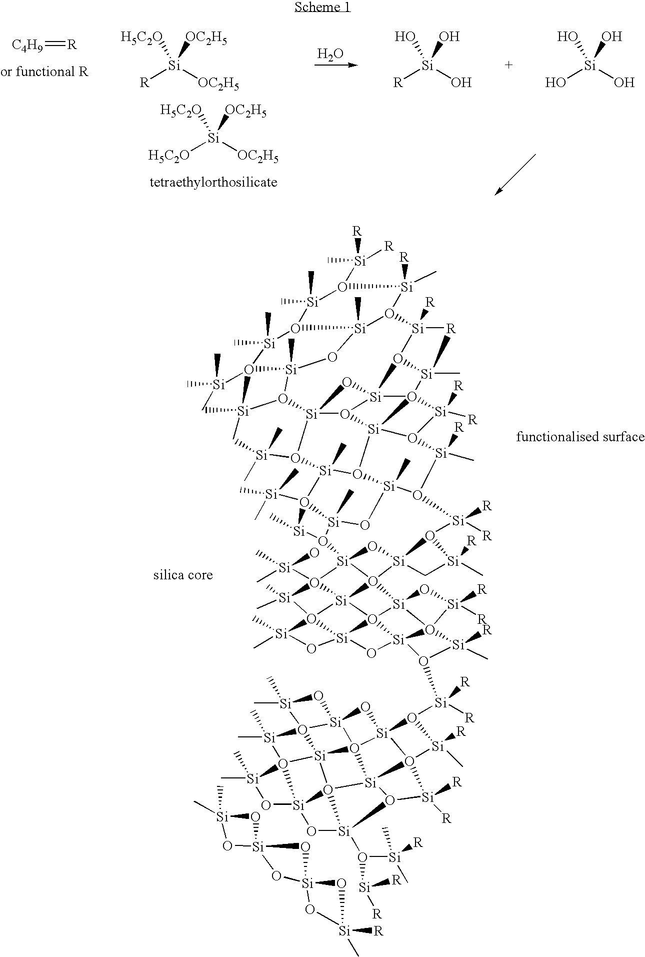

Functionalised POSS and nano silica particles can be coupled (cross linked) to the polymer matrix. Alternatively the reactive groups of the functionalised POSS or nano silica particles can be used to bind bio-active or other active species such as, for example, proteins or DNA to the doped polymer. Advantageously nano particulate silica particles employed as dopant are of the order of from 10 nm to 80 nm in diameter, preferably 20 nm to 50 nm in diameter, more preferably, 40 nm in diameter.

Advantageously the polymer of the invention comprises a mixture of different compounds of general formula I. Using mixed compounds of formula I allows the properties of the polymer to be adjusted to suit the application. For example solubility in selected solvents and hardness of a polymer of the invention can be adjusted by choice of compounds of formula I and the relative proportion of each used to produce the polymer.

Preferably when the core group A is an aliphatic hydrocarbon the number of carbon atoms is ten or less. With hydrocarbons of more then ten carbon atoms crystallisation may occur in the polymer, reducing the light transmission and making the polymer brittle.

Advantageously where the core group A is a polydialkysiloxane of general formula II or the compound of general formula I is a polydialkylsiloxane of formula III the alkyl groups R² are methyl. Functionalised polydimethyl-disiloxanes are commercially available and can readily be made into compounds of general formula I as described hereafter.

A number of compounds of general formula I are commercially available. Examples include the compounds shown in Scheme 2 below, trimethylolpropane triglycidyl ether (structure 1), 1,4-cyclohexanedimethanol diglycidyl ether (2), Poly(dimethylsiloxane)diglycidyl ether terminated (3), 1,4-butanediol diglycidyl ether (4), 1,4-cyclohexanedimethanol divinyl ether (5), 1,4-butanediol divinyl ether (6). The molecular weight of the polydimethylsiloxane compound (3) is typically selected to be between 740 and 64000. Novel vinyl ether functionalised compounds have also been synthesised and used to produce polymers of the invention and their synthesis is described later.

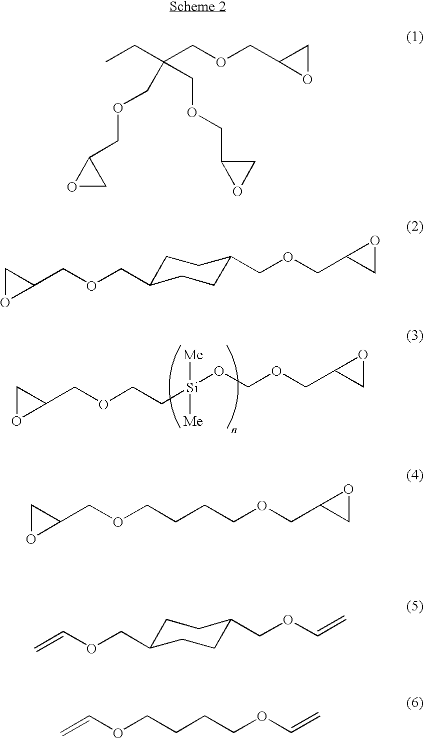

Preferably the core group A has at least two functional groups attached as shown in the examples of Scheme 2. This ensures that the polymers have a high degree of cross-linking, adding to their strength and durability. In the examples shown the functional groups in each compound are the same, i.e. glycidyl ether or vinyl ether, but it will be understood that they may be different. For example a compound of formula I may have both glycidyl ether and vinyl ether functional groups.

By controlled polymerisation of compounds of general formula I a polymer with a selected proportion of residual functional groups can be prepared. These residual functional groups provide surface functionalisation and can be used to attach modifying groups to the polymer. For example bio-active materials to produce a polymer for use in DNA probes or nano-composites. For example, amine functionality can be added to the polymer surface by reaction at the functional groups. The amine functions can, for example, have single stranded DNA or peptides attached. These can then be used for bio assays such as DNA hybridisation probe experiments. Alternatively, groups that will change the hydrophobic/hydrophilic nature of the polymer surface may be attached to the amine link, to modify the physical properties of the polymer.

The polymers of the invention are obtainable by a polymerisation of compounds of general formula I.

Advantageously they are obtainable by cationic polymerisation. Preferably they are obtainable by photo-initiated cationic polymerisation of compounds of general formula I.

Thus according to a second aspect the present invention provides a method for the production of a of an ultra violet light transmitting polymer comprising the steps of:
a) providing a mixture comprising at least one compound of general formula I and a photo acid generator;
b) Irradiating the mixture with light of a wavelength suitable to decompose the photo acid generator whereby an acid catalyst is formed to polymerise the compounds of general formula I.

For many applications, for example coating a substrate such as an LED, the mixture of compounds of general formula I and the photo acid generator, may be spun coated onto the substrate, in a conventional manner, before the polymerisation step (b). In such cases the mixture may also comprise a suitable organic solvent or ‘developer’ to facilitate the coating process and the method of the invention may also include a heating step (a ‘pre-bake’ step) to remove solvent before illumination of the mixture. Typical solvents that can be employed include acetonitrile, acetone, toluene or mixtures thereof.

For some applications the viscosity of the mixture of compounds of formula I, with or without added solvent may not be appropriate. For example a low viscosity may result in a mixture that cannot be, for example, spin coated to produce a polymer layer of the desired thickness. Therefore, advantageously the polymerisation step b) is stopped when a partially polymerised ‘pre-polymer’ has been formed. The pre-polymer has a higher viscosity than the original mixture to facilitate a further processing step. The method of the invention then comprises an additional processing step wherein the pre-polymer is subjected to further irradiation to complete polymerisation (‘curing’). Advantageously the additional processing step may include the addition of more photo acid generator if required.

Advantageously the additional processing step includes the addition of further compounds of general formula I to the pre-polymer before irradiation to the product.

Thus it is possible to adjust viscosity to suit the processing conditions for completion of polymerisation, even when some of the selected compounds of general formula I have a low viscosity. For example, where the core group A is a small aliphatic group of ten carbon atoms or less. Adding further compounds of formula I to a pre-polymer gives a further opportunity to adjust the properties of the polymer product.

The photo acid generators (PAGs) are compounds which on irradiation decompose and react with a substrate (e.g. a compound of general formula I) to form an acid HX which catalyses the cationic polymerisation of a compound of general formula I as shown in scheme 3 below in respect of 1,4-cyclohexanedimethanol diglycidyl ether.

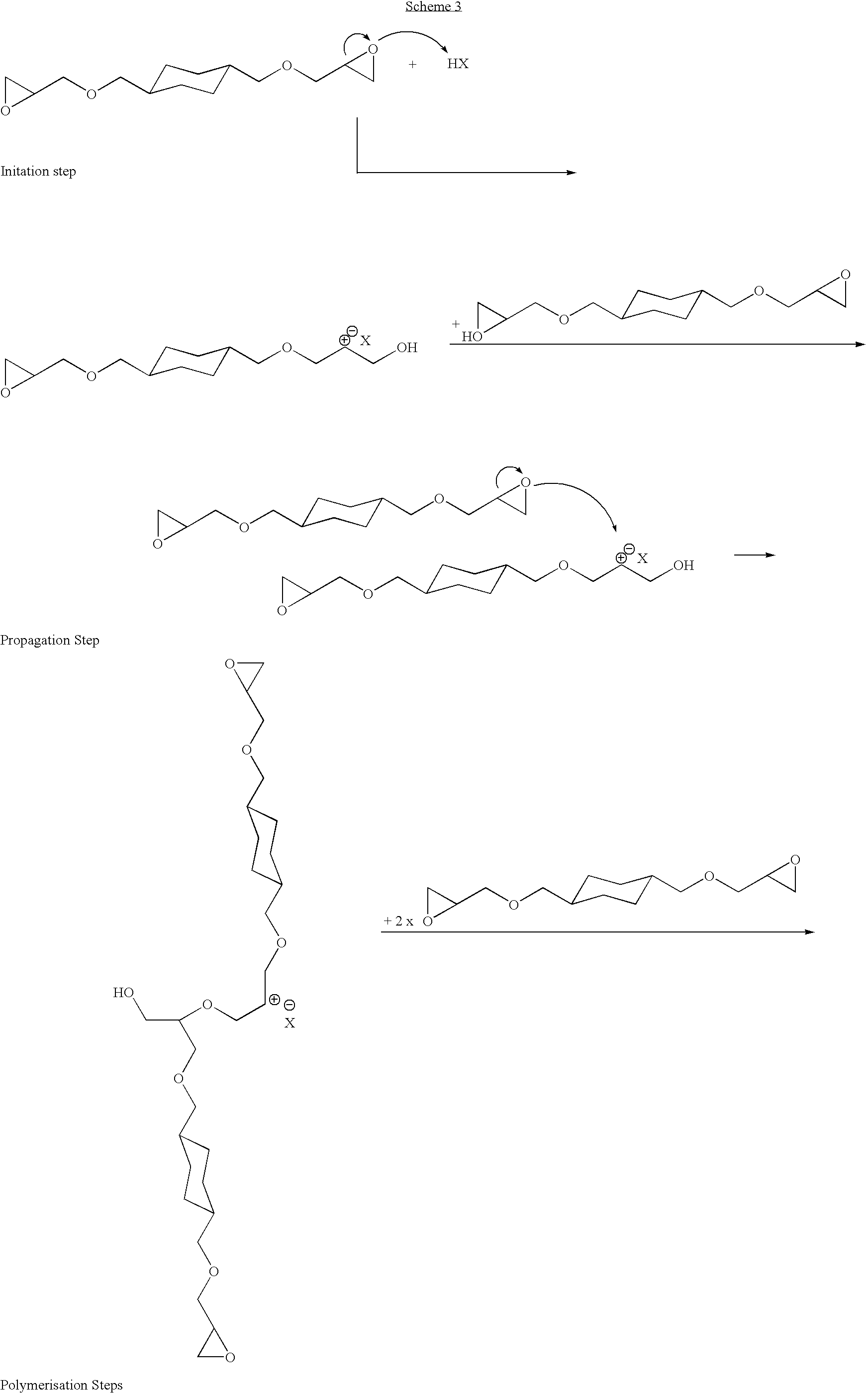

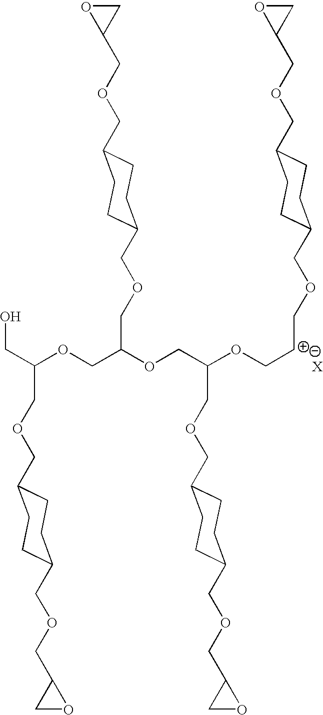

Preferably the photo acid generators decompose on irradiation with UV light of a wavelength of between 250 nm-350 nm. Preferred photo acid generators are commercially available and include triarylsulfoniumhexafluoro phosphates (7), triaryl sulfoniumhexafluoro antimonates (8), diaryliodium hexafluoro phosphates (9) and p(hexyloxyphenyl)phenyl iodinium hexafluoro antimonate (10). Preferably the aryl groups are phenyl, as shown below in Scheme 4, but other compounds with suitably UV absorbing aryl groups other than phenyl can be used.

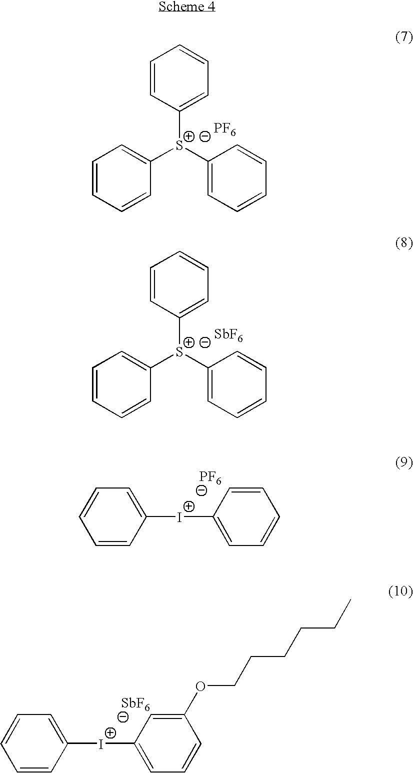

The preferred photo acid generators have several advantages. Their decomposition and hence the polymerisation reaction can be initiated by UV light. This allows polymer coating of a UV transmitting LED to be achieved by using light produced by the LED itself to cause polymerisation. The UV LED is coated with a mixture comprising compounds of general formula I and/or a pre-polymer formed from compounds of general formula I together with a selected photo acid generator. The LED can then be switched on for a pre-determined period to cure the polymer, forming a coating or a lens on the LED. Residual, unreacted material can then be washed away with a suitable solvent. Furthermore, on reaction, the preferred PAGs decompose to products with a reduced UV absorbance i.e. a photo acid bleaching process occurs, and so at least when used in preferred concentrations the PAG, do not interfere significantly with the UV transparency of the finished polymer. [Reference: Photodecomposition Pathways for Triphenylsulfonium Salts from the Singlet and Triplet Excited States; Welsh, K. M., et al. Abstracts Of Papers Of The American Chemical Society, 1989. 198: p. 41-PMSE.]

The photo acid generator used depends on the desired UV wavelength used for polymerisation and the compatibility with the compounds of formula I or pre-polymer. The triphenyl systems are incompatible (insoluble) with compounds having vinyl ether functional groups, both with alkyl core groups and polydialkysiloxane core groups and so are used only where epoxy (glycidyl ether) functional groups are to be polymerised.

The triaryl compounds may be used in a range from 0.2% to 2% by weight of photo acid generator in the mixture to be polymerised. Preferably the triaryl compounds are used in a range of from 0.5% to 1% by weight of photo acid generator in the mixture to be polymerised. Below a concentration of 0.5% polymerisation does occur but the product tends to have poor mechanical properties (e.g. be too soft). When used at a concentration above 1% the UV transparency of the polymer product is reduced, despite the photo acid bleaching effect. Diaryl PAGs may be used in the same concentration range, from 0.2% to 2% by weight of photo acid generator in the mixture to be polymerised. For the diaryl PAGs the preferred concentration range is from 0.35% to 0.7% for the same reasons as described for the preferred range for the triaryl compounds.

Polymers made with triaryl PAGs can be cured using light with a wavelength of from 250 nm to 400 nm. The maximum cure rates found are at 251 nm and 368 nm. The diaryl PAGs will typically cure using light between 250 nm and 325 nm.

In general, without wishing to be restricted in any way in terms of the use of particular compounds of general formula I in a particular application, three types of polymer systems made by the method of the invention can be identified.
a) Where the core group A is an aliphatic hydrocarbon, which may contain a ring, and the final polymer product of the method is produced directly from the compounds of formula I, without a pre-polymer forming step. These ‘monomeric systems’ i.e. where the polymer is formed directly from small (not polydialkylsiloxane) compounds of formula I, are not generally useful for spin coating applications due to their low viscosity. However, when a self-alignment process is required, as described below in respect of lens applications or the polymer is cured by light passing through a mask, such systems can produce a polymer with a high degree of surface functionality where the functional groups are glycidyl ethers.
   The ‘monomeric’ systems are also particularly useful for moulding applications, to form microstructures as their low viscosity lends itself to accurate reproduction of the mould shape. Typical viscosities of the monomers are from 100-300 cps at 25° C.
b) Where spin coating or other processing requiring a more viscous fluid is to be carried out the use of a pre-polymer and/or compound containing poly dialkyl siloxanes is advantageous. For example, a pre-polymerised 1,4-cyclohexanedimethanol diglycidyl ether ((2) in Scheme 1) can be used with viscosity adjusted by adding more or less of the unreacted cyclohexylglycidyl ether to the pre-polymer before spin coating and carrying out the final irradiation step of the method of the invention.
   As an alternative molecules of formula I with polyldialkylsiloxane containing core groups can be used. For example, a compound of general formula III with glycidyl ether functional groups and a molecular weight of ˜750 can be blended with a compound of general formula II having molecular weights of between 18,000-45,000 to produce a range of mixtures suitable for polymerising by the method of the invention, especially in spin coating applications. Typically pre-polymer and polydimethyl siloxane mixtures such as described above an be used to produce coatings of from 15 to 45 microns thick depending on the spin speed (4500-2000 rpm) employed in a conventional spin coating process.
c) For lithographic applications or other applications where a high level of cross linkage is desired a more complex mixture may be employed in the method of the invention. A high level of cross linking in the polymer after exposure to light is desirable in photolithographs as it allows more powerful solvents to be used to wash away un-exposed mixture leading to polymer structures with excellent resolution.

A particularly preferred lithographic grade polymer of the invention is made from 70-80% of a pre-polymerised 1,4 cydohexanedimethanol diglycidyl ether (2), 19-29% of trimethylolpropane triglycidyl ether (1) and either 1% triaryl photo acid generator or 0.7% diaryl photo acid generator. Such mixtures have been found to be particularly effective where harsh solvents are used to wash away unpolymerised material, avoiding loss of definition of the structure of the article made with the polymer. A concentration of 19% or more of the triglicydyl ether (1) gives a high degree of cross-linking in this system but using more than 29% reduces the UV light transmission.

The polymers and methods of the invention are particularly suited to a number of different applications. Examples of use include, but are not limited to, coating or encapsulating light emitting diodes (LEDs) (visible or ultra violet,especially deep UV (240-350 nm) emitting LEDs), optical components, fibre optics, electronic components and assemblies.

Encapsulation of optoelectronic components and systems can include devices such as an Organic Light Emitting Diode display. Other devices that may be coated or encapsulated include optical data storage media, for example blue ray DVD media and future media requiring UV transmission in use.

The polymers of the invention may also be used in solid-state lighting applications. They can be blended with or used to encapsulate, or used in a multiple sandwich (layered) structure with, light emitting polymers. Other orientations may be used to incorporate the light emitting polymers in the polymer of the invention. Light emitting polymers are used to convert one wavelength of light to one, or more, other wavelengths of light. For example, an UV light source can be used in conjunction with commercially available polymers to produce for example, red or green or blue light. By combining colours white light can be produced. The colour of light emitted can be manipulated by blending different combinations of for example red and/or green and/or blue light emitting polymers.

The polymers can also find use as photo resists and in photolithography where UV light is used and lenses suitable for use with deep UV light emitters.

The polymers and methods of the invention find particular use in the fabrication of lenses for UV emitting LED's which currently require mounting in TO cans with optical windows of quartz, sapphire or diamond. For example the polymers of the present invention can be used to provide the domed encapsulation, typically used with visible light LEDs, to a UV LED. UV LEDs coated with, encapsulated by, or having a lens arrangement, comprising polymers of the invention constitute a further aspect of the present invention.

A particularly advantageous use of the polymers of the invention and the methods of the invention arises where it is desired to fit a UV LED with a lens arrangement for focussing and/or collimating the light emitted. As previously mentioned utilising the UV light from an LED being coated to initiate the decomposition of the PAG can carry out the method of the invention. This means that a self aligned coating or lens can be manufactured in situ on the light-emitting surface of an LED. For example, a mixture of compounds of formula I and a PAG is applied across the surface of an array or micro array of UV LEDs. The LEDs are switched on for a pre-determined time producing a desired quantity of polymer of the invention in the vicinity of each LED. The unpolymerised mixture, more distant from each LED is then washed away with a suitable solvent to leave each LED with an accurately aligned coating or lens attached to it.

The polymers of the invention can also be moulded to form microstructures suitable for use in microfluidics or waveguide applications.

Other preferred uses of the polymers include as a material for the manufacture of cuvettes, microscope slides and the like. The polymers have good UV and visible light transmission making them particularly suited to analytical applications where a sample in a cuvette or on a slide is investigated by use of visible and/or UV light.

### BRIEF DESCRIPTION OF THE DRAWINGS

Further preferred features and advantages of the present invention will appear from the following detailed description of some embodiments illustrated with reference to the accompanying drawings in which:

FIG. 1 shows the UV transmission curve of a polymer of the invention in comparison with a prior art polymer; and

FIG. 2 shows the UV transmission curve of two other polymers of the invention in comparison with a prior art polymer.

### DESCRIPTION SOME PREFERRED EMBODIMENTS AND EXPERIMENTAL RESULTS

Examples of Novel Compounds of Formula I

As previously discussed a number of compounds of general formula I are commercially available and can be used to produce polymers of the invention. The manufacture of two novel compounds of general formula I is described here. Compound A has a core group A conforming to general formula II and compound B has a structure conforming to general formula III, as described above.

Preparation of poly(dimethylsiloxane)divinyl ether Terminated Compound A and poly(dimethylsiloxane)divinyl Terminated Compound B.

Preparation of 1-Allyloxy-(2-vinyloxy)ethane

Into a 250 mL round bottom flask fitted with a magnetic stirrer, reflux condenser and nitrogen inlet were placed 21.16 g (0.24 mol) of 2-(vinylether)ethanol, 29.04 g (0.24 mol) of allyl bromide, 9.6 g (0.24 mol) of NaOH pellets, 3.6 g (0.01 mol) of tetra-n-butylammonium bromide (phase transfer catalyst) and 80 mL of hexane. The mixture was stirred and heated to 70° C. and held at that temperature for 18 hours.

After cooling the mixture to room temperature it was filtered and poured into 200 mL of deionised water. Then the organic layer was separated and washed twice with deionised water. The water phases were combined and washed twice with hexane. Then all the organic phases were combined and the hexane was removed on a rotary evaporator giving 24.7 g (0.19 mol) of 1-allyloxy-(2-vinyloxy)ethane. Yield: 79%.

### Isomerisation of 1-Allyloxy-(2-vinyloxy)ethane to 1-(1-Propenoxy)-(2-vinyloxy)ethane

24.7 g (0.19 mol) of 1-allyloxy-(2-vinyloxy)ethane and 43.26 g (0.38 mol) and 200 mL of DMSO were stirred under a nitrogen blanket for 1.5 hours.

The mixture was cooled to room temperature and poured into 500 mL of deionised water. The solution was extracted twice with diethyl ether. The ethereal phases were combined and washed with deionised water and then dried over anhydrous Na₂SO₄. The solvent was removed on a rotary evaporator and the product was distilled under a pressure of 1.0 mmHg at 65° C. to give 9.42 g (0.074 mol) of 1-(1-propenoxy)-(2-vinyloxy)ethane. Yield: 36%.

### Chemoselective Hydrosilation of 1-(1-propenoxy)-(2-vinyloxy)ethane with poly(dimethylsiloxane), Hydride Terminated (Mₙ=580). (Compound A)

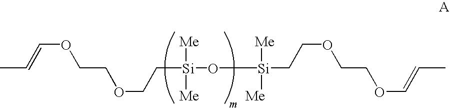

A mixture of 2.21 g (17.24 mmol) of 1-(1-propenoxy)-(2-vinyloxy)ethane, 5 g (8.62 mmol) of hydride terminated PDMS (polydimethylsiloxane), 15.66 mg (1.7×10⁻⁵ mol) of Wilkinson's catalyst and 15 mL of dry THF were stirred at 60° C. under a nitrogen blanket for 18 hours. The mixture was cooled to room temperature and Wilkinson catalyst was removed via flash chromatography on silica. Solvent was diethylether, which was removed using a rotary evaporator giving a quantitative yield.

### Chemoselective Hydrosilation of 1-(1-propenoxy)-(2-vinyloxy)ethane with (5-7% methylhydrosiloxane)-(dimethylsiloxane) Copolymer (Mₙ=60000-65000) (Compound B)

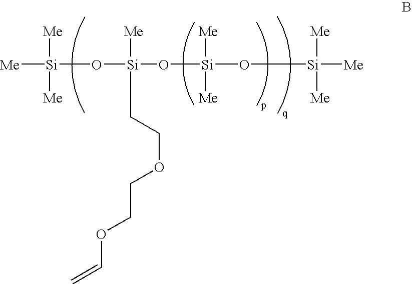

A mixture of 1.32 g (10.24 mmol) of 1-(1-propenoxy)-(2-vinyloxy)ethane, 10 g (0.16 mmol) of hydride functionalised PDMS, 9.21 mg (1.0×10⁻⁵ mol) of Wilkinson's catalyst and 30 mL of dry THF were stirred at 60° C. under a nitrogen blanket for 18 hours.

The mixture was cooled to room temperature and Wilkinson catalyst was removed via flash chromatography on silica. Solvent was diethylether, which was removed using a rotary evaporator giving a quantitative yield.

Polymers of the Invention

The production of five exemplary types of polymers of the invention “(HTP1,HTP2,HTP3,HTP4” and “LITH1” are described below. Table 1 (below) shows the wavelength of light and time of irradiation used in the final cure.

HTP1.

Pre-Polymerisation

20 g of cyclohexanedimethanol diglycidyl ether and 0.20-0.50% wt/wt of the photo initiator are added to a beaker, under constant stirring the mixture is exposed to a 3 mW cm⁻² 368 nm wavelength light, for around 10 min or when the reaction mixture reaches 70 C. To this pre-polymer 20 g of acetonitrile is added, the system is then filtered through a Millipore filter.

Cure

To the pre-polymer 1 wt % of Triphenyl sulfonium hexafluoro phosphate or 0.7 wt % Triphenyl sulfonium hexafluoro antimonate is added and the resulting polymer is spun and the final cure conditions (light wavelength and time) are given in the Results Table 1.

HTP 2

This was manufactured from the same materials and by the same process, including formation of a pre-polymer, as HTP1 except that the photo acid generator used was diphenyl iodinium hexafluoroantimonte. This system will only cure at 310 nm and below.

HTP 3

1,4-Cyclohexanedimethanol divinyl ether was polymerised without a pre-polymer manufacturing step being employed. The photo acid generator was p(oxyphenyl)phenyl iodinium hexafluoroantimonate, the cure characteristics are give below in Table 1.

HTP4

HTP 4 used 99% of a glycidyl ether functionalised poly(dimethylsiloxane), directly analogous to the vinyl ether functionalised compound A (molecular weight 40000) as described above. The glycidyl ether functionalised poly(dimethylsiloxane) was polymerised with 1% p(oxyphenyl) phenyl iodinium hexafluoroantimonate used as the photo acid generator. Materials with similar or improved properties can be made using compound A or B as described above or a mixture of compounds A and B. The replacement of glycidyl ether functionality with vinyl ether functionality confers improved transparency on the final product and greater reactivity during polymerisation.

LITH 1

This is an example of the highly cross linked ‘lithographic grade’ mentioned earlier and was formed by taking a mixture of 75% of a pre-polymer formed from 1,4-cyclohexane dimethanol diglycidyl ether as described above for HTP 1, with 24% of trimethylolpropane triglycidyl ether and 1% of Triphenyl sulfonium hexafluoro phosphate. Generally polymers of this type can be made using 70%-80% of a pre-polymer formed from cyclohexane dimethanol diglycidyl ether and adding 19%-29% of trimethylolpropane triglycidyl ether before curing with 1% of a triaryl photo acid generator or 0.7% of a diaryl acid generator.

The results of testing of the four polymers described above are given in Table 1 where there solvent resistance, glass transition temperatures (Tg) and transparencies are shown. Other characteristics are discussed below.

TABLE 1

| | HTP1 | HTP2 | HTP3 | HTP4 | LITH1 |
|---|---|---|---|---|---|
| Viscosity | | | <100 cps | | |
| Cure | S | I | I | I | S and I |
| Wavelength | | | | | |
| Cure time¹ | 400 sec | 200 sec | 100 sec | 3000 sec | 300 and 150 sec |
| Developer | Acetonitrile | Acetonitrile | Toluene + | Acetonitrile | Acetonitrile |
| | | | Acetone | | |
| Solvent | Poor | Poor | Good | V. Good | V. Good² |
| Resistance | | | | | |
| Surface | Glycidyl | Glycidyl | Vinyl | Glycidyl | Glycidyl |
| Functionality | Ether | Ether | Ether | Ether | Ether |
| Tg/° C. | 45 | 45 | — | — | 54 |
| Transparency % | 20 micron | 20 micron | 20 micron | 160 micron | 20 micron |
| 220 nm | 20 | 50 | 45 | 40 | 5 |
| 250 nm | 45 | 80 | 85 | 95 | 25 |
| 280 nm | 60 | 95 | 95 | 99 | 50 |
| 320 nm | 99 | 99 | 99 | 99 | 90 |

¹Using standard 5 mW cm² source at 254 nm = I and 368 nm = S

Polymer HTP 1 and similar types are versatile. The viscosity of the pre-polymer can be adjusted for a given application and wavelengths of up to 400 nm can be used to effect polymerisation. It can be made to have nearly 90% transmission at 280 nm and above when in a 20 micron thick layer. This system is ideally suited to micro LED optics and other micro optic applications and has good thermal resistance being useable at up to 160 deg C.

HTP 2 polymer and related polymers using diphenyl iodinium hexafluoroantimonte as photo-acid generator have improved transmission characteristics with respect to HTP 1 being suited to use in micro LED structures at wavelengths of from 250 nm. It is equally suitable for use in micro optics and with micro LEDs.

HTP 3 has very low viscosities and cannot be cured above 325 nm. HTP3 and similar polymers have improved temperature resistance, up to 200° C., in comparison with epoxy functionalised materials (HTP1,HTP2), as under thermal stress epoxy groups are converted to acid groups. Therefore vinyl ether groups provide materials with superior temperature resistance. HTP3 also has a higher UV transparency than HTP 1 and HTP 2 systems.

HTP 4 has exceptionally high transmission characteristics as shown by the measurements in Table 1 taken on a 160 micron thick film rather than the 20 micron thick films of the other examples. Films of 200 micron thick can show transmission of up to 80% at 250 nm and this material can be used to encapsulate LEDs producing UV light down to 220 nm.

The LITH 1 polymer has exceptional solvent resistance particularly suited to lithographic applications as discussed earlier.

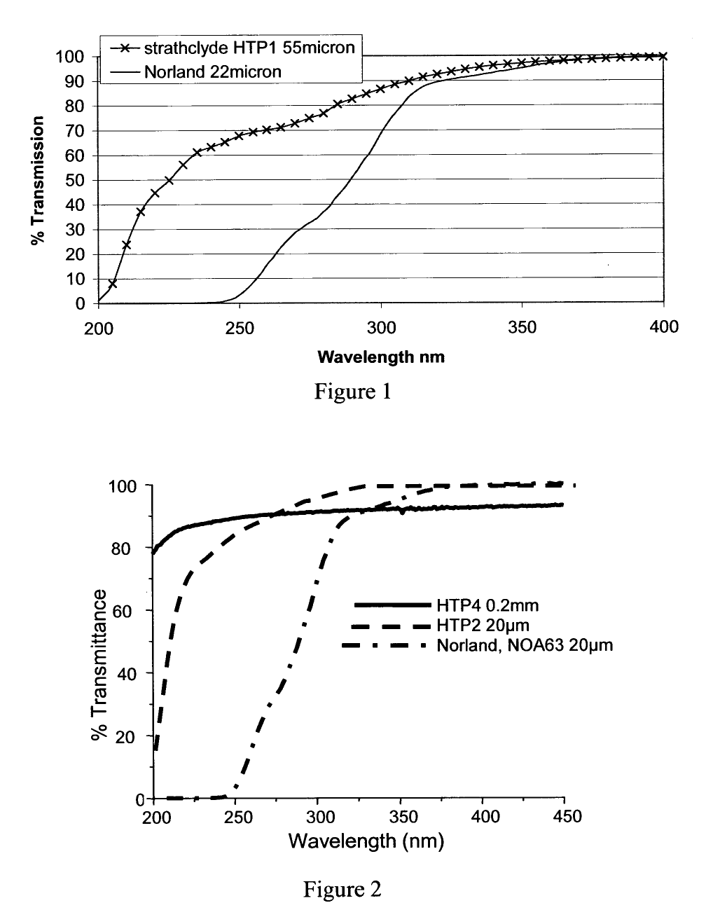

UV light transmission results for HTP 1 polymer are shown in FIG. 1 in comparison with a commercially available polymer Norland NOA63 (Norland Optical), which has been successfully used with an LED source emitting at 368 nm [Dawson M D, Girkin J M, Liu C, Gu E, Jeon C W, Polymer microlens arrays applicable to AlInGaN ultraviolet micro-light-emitting diodes, IEEE Photonics Tech. Lett., 17(9), 2005, p 1887] The Norland NOA63 was at a 20 micron thickness and the HTP 1 polymer at 55 microns, illustrating the greatly improved transmission at wavelengths below 300 nm of a layer of HTP 1 even at a substantially greater thickness.

FIG. 2 shows a similar comparison between a 0.2 mm thick sample of HTP4 polymer and a 20 micron sample of HTP2 polymer with the Norland NOA63 polymer (20 micron) as before. The graph shows the superior transmission of the samples of HTP2 and HTP4 at wavelengths below 300 nm. The 0.2 mm layer of HTP4 is substantially better than Norland NOA63 polymer of only 20 microns thickness.

1. An ultra violet light transmitting polymer obtainable by the polymerisation of at least one compound of general formula I: 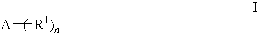
wherein n is a positive integer and A is a substantially non UV absorbing core group comprising;
linear or branched aliphatic hydrocarbons which may contain an aliphatic ring; or
polydialkylsiloxanes of general formula II: 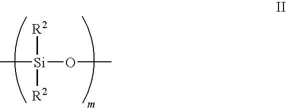
wherein each of the groups R² are independently a C₁-C₁₀ alkyl or cycloalkyl group and m is a positive integer and the polydialkylsiloxane chain may be branched; or
the compound of general formula I is a polydialkylsiloxane of general formula III: 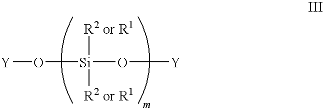
wherein the groups Y are, independently, end capping groups of the form: 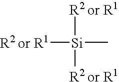
and
R² and m have the same meaning as before and the polydialkylsiloxane chain may be branched; and wherein each R¹ is independently, a functional group comprising: 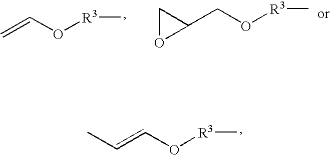
and each of the groups —R³— are, independently, linking groups which may be present or absent and, where present, may be a C₁ to C₁₀ hydrocarbon chain, which may contain an ether linkage.

2. An ultra violet light transmitting polymer according to claim 1 wherein the core group A is an aliphatic hydrocarbon of ten or less carbon atoms.

3. An ultra violet light transmitting polymer according to claim 1 wherein the core group A comprises polydialkylsiloxanes of general formula II which have a molecular mass of from 740 to 64000.

4. An ultra violet light transmitting polymer according to claim 1 wherein the core group A is a polydialkylsiloxane of general formula III which have a molecular mass of from 700 to 45000.

5. An ultra violet light transmitting polymer according to claim 1 wherein the core group A is a polydialkylsiloxane of general formula III and the ratio of R¹ to R² groups is between 1:8 and 1:16.

6. An ultra violet light transmitting polymer according to claim 1 where the core group A is a polydialkysiloxane of general formula II or the compound of general formula I is a polydialkylsiloxane of formula III, wherein the alkyl groups R² are methyl.

7. An ultra violet light transmitting polymer according to claim 1 wherein the polymer further comprises dopants.

8. An ultra violet light transmitting polymer according to claim 6 wherein the dopants are selected from the group consisting of bisphenol A, nano particulate silica, functionalised nano particulate silica, polyhedral oligiomeric silisesquioxane, functionalised polyhedral oligiomeric silisesquioxane and nanoclays.

9. An ultra violet light transmitting polymer according to claim 1 obtainable by the polymerisation of a mixture of different compounds of general formula I.

10. An ultra violet light transmitting polymer according to claim 1 wherein core group A has at least two functional groups attached.

11. An ultra violet light transmitting polymer according to claim 1 wherein the polymer is obtained by cationic polymerisation of compounds of general formula I.

12. An ultra violet light transmitting polymer according to claim 1 wherein the polymer is obtained by photo-initiated cationic polymerisation of compounds of general formula I.

13. A method for the production of an ultra violet light transmitting polymer comprising the steps of:
a) providing a mixture comprising a photo acid generator and at least one compound of General formula I: 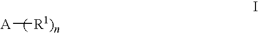
wherein n is a positive integer and A is a substantially non UV absorbing core group comprising;
linear or branched aliphatic hydrocarbons which may contain an aliphatic ring; or
polydialkylsiloxanes of general formula II: 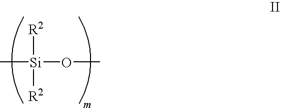
wherein each of the groups R² are independently a C₁-C₁₀ alkyl or cycloalkyl group and m is a positive integer and the polydialkylsiloxane chain may be branched; or
the compound of general formula I is a polydialkylsiloxane of general formula III: 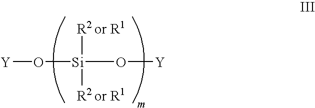
wherein the groups Y are, independently, end capping groups of the form: 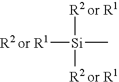
and
R² and m have the same meaning as before and the polydialkylsiloxane chain may be branched; and
wherein each R¹ is independently, a functional group comprising: 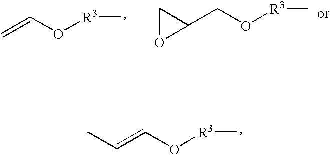
and each of the groups —R³— are, independently, linking groups which may be present or absent and, where present, may be a C₁ to C₁₀ hydrocarbon chain, which may contain an ether linkage; and
b) irradiating the mixture with light of a wavelength suitable to decompose the photo acid generator whereby an acid catalyst is formed to polymerise the compound of general formula I.

14. A method for the production of an ultra violet light transmitting polymer according to claim 13 wherein the mixture is spin coated onto a substrate, before the polymerisation step (b).

15. A method for the production of an ultra violet light transmitting polymer according to claim 14 wherein the mixture further comprises an organic solvent to facilitate the coating process.

16. A method for the production of an ultra violet light transmitting polymer according to claim 15 wherein the organic solvents are selected from the group consisting of acetonitrile, acetone, toluene and mixtures thereof and the method includes a heating step to remove solvent before illumination of the mixture.

17. A method for the production of an ultra violet light transmitting polymer according to claim 13 wherein the polymerisation step b) is stopped when a partially polymerised pre-polymer has been formed; and the method further comprises an additional processing step wherein the pre-polymer is then subjected to further irradiation to complete polymerisation.

18. A method for the production of an ultra violet light transmitting polymer according to claim 17 wherein the additional processing step includes the addition of more photo acid generator to the pre-polymer.

19. A method for the production of an ultra violet light transmitting polymer according to claim 17 wherein the additional processing step includes the addition of at least one further compound of general formula I to the pre-polymer before irradiation to complete polymerisation.

20. A method for the production of an ultra violet light transmitting polymer according to claim 13 wherein photo-acid generators that decompose on irradiation with UV light of a wavelength of between 250 nm-350 nm are employed.

21. A method for the production of an ultra violet light transmitting polymer according to claim 13 wherein the photo acid generators are selected from the group consisting of triarylsulfoniumhexafluoro phosphates, triaryl sulfoniumhexafluoro antimonates, diaryliodium hexafluoro phosphates and p(hexyloxyphenyl)phenyl iodinium hexafluoro antimonate.

22. A method for the production of an ultra violet light transmitting polymer according to claim 13 wherein the photo acid generators are triaryl compounds and are used in a range of from 0.2% to 2% by weight in the mixture to be polymerised.

23. A method for the production of an ultra violet light transmitting polymer according to claim 22 wherein the photo acid generators are triaryl compounds and are used in a range of from 0.5% to 1% by weight in the mixture to be polymerised.

24. A method for the production of an ultra violet light transmitting polymer according to claim 13 wherein the photo acid generators are diaryl compounds and are used in a range of from 0.2% to 2% by weight in the mixture to be polymerised.

25. A method for the production of an ultra violet light transmitting polymer according to claim 24 wherein the photo acid generators are diaryl compounds and are used in a range of from 0.35% to 0.7% by weight in the mixture to be polymerised.

26. A method for the production of an ultra violet light transmitting polymer according to claim 13 wherein the polymerisation is controlled to provide a polymer with a selected proportion of residual functional groups.

27. A method for the production of an ultra violet light transmitting polymer according to claim 26 further comprising the step of providing amine functional groups at the polymer surface by reaction at the residual functional groups.

28. An ultra violet light-transmitting polymer produced by the method as claimed in claim 13.

29. A polymer for use in lithographic applications obtainable by the polymerisation of 70-80% of a pre-polymerised 1,4 cydohexanedimethanol diglycidyl ether, 19-29% of trimethylolpropane triglycidyl ether and from 0.2% to 2% of a triaryl photo acid generator or a diaryl photo acid generator.

30. A polymer for use in lithographic applications according to claim 29 wherein either from 0.5% to 1% of a triaryl photo acid generator or from 0.35% to 0.7% of a diaryl photo acid generator is used.

31. Use of a polymer according to claim 1 as a photoresist; in a photolithography process; as a coating, encapsulant or lens for a light emitting diode; as a coating or encapsulant for optoelectronic or electronic components and assemblies; as a coating for fibre optics; in the coating or encapsulation of optical storage data; or in the foimation of a microstructure for microfluidics or waveguide applications.

32. Use of a polymer according to claim 31 as a coating, encapsulant or lens for a light emitting diode, wherein the light emitting diode is a UV light emitting diode.

33. Use of a polymer according to claim 1 in a solid state lighting device wherein at least one light emitting polymer is incorporated or encapsulated in the polymer.

34. Use of a polymer according to claim 1 in a cuvette or microscope slide.

35. An array or micro array of UV light emitting diodes coated with, encapsulated by, or having lenses, comprising a polymer according to claim 1.

36. A method for the in situ provision of self aligned coatings or lenses to a UV light emitting diode or an array of said diodes, the method comprising the steps of: providing a mixture comprising a photo acid generator and at least one compound of general formula I: 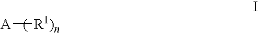
wherein n is a positive integer and A is a substantially non UV absorbing core group comprising;
linear or branched aliphatic hydrocarbons which may contain an aliphatic ring; or
polydialkylsiloxanes of general formula II: 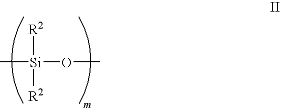
wherein each of the groups R² are independently a C₁-C₁₀ alkyl or cycloalkyl group and m is a positive integer and the polydialkylsiloxane chain may be branched; or
the compound of general formula I is a polydialkylsiloxane of general formula III: 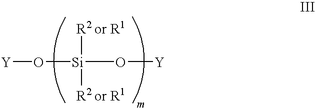
wherein the groups Y are, independently, end capping groups of the form: 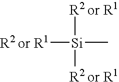
and
R² and m have the same meaning as before and the polydialkylsiloxane chain may be branched; and
wherein each R¹ is independently, a functional group comprising: 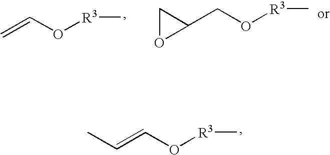
and each of the groups —R³— are, independently, linking groups which may be present or absent and, where present, may be a C₁ to C₁₀ hydrocarbon chain, which may contain an ether linkage;
b) applying said mixture to the surface of a UV light emitting diode or an array or micro array of UV light emitting diodes;
c) switching on the UV light emitting diode or diodes for a selected period of time; and
d) removing mixture not polymerised during step c) from the vicinity of the UV light emitting diode or diodes.

37. A method according to claim 36 further comprising the step of partially polymerising the mixture to form a pre-polymer, before applying it the UV light emitting diode or diodes.

38. A compound according to general formula A: 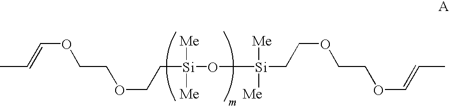
wherein m is a positive integer.

39. A compound according to claim 38 wherein the molecular mass is from 740 to 64000.

40. A compound according to general formula B: 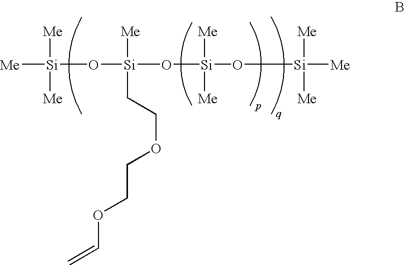
wherein p and q are positive integers.

41. A compound according to claim 40 wherein the molecular mass is from 700 to 45000.

42. A compound according to claim 40 wherein the ratio of groups: 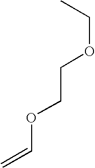
to methyl groups is between 1:8 and 1:16.
